(19) United States
(12) Patent Application Publication
(10) Pub. No.: US 2025/0233060 A1
(43) Pub. Date: Jul. 17, 2025

(54) SEMICONDUCTOR PACKAGE STRUCTURE WITH GLASS SUBSTRATE AND PACKAGING METHOD THEREOF

(71) Applicant: Yangtze Memory Technologies Co., Ltd., Wuhan (CN)

(72) Inventors: Xinru ZENG, Wuhan (CN); Peng CHEN, Wuhan (CN)

(73) Assignee: Yangtze Memory Technologies Co., Ltd., Wuhan (CN)

(21) Appl. No.: 18/422,342

(22) Filed: Jan. 25, 2024

(30) Foreign Application Priority Data
Jan. 17, 2024 (CN) 202410069355.X

(51) Int. Cl. H01L 23/498; H01L 21/48; H01L 21/768

(52) U.S. Cl. CPC H01L 23/49827; H01L 21/4825; H01L 21/76898; H01L 23/49816

(57) ABSTRACT

A semiconductor package structure includes a substrate structure that includes a glass substrate and a through-glass interconnection structure. The glass substrate has a bottom surface and a top surface opposing the bottom surface. The through-glass interconnection structure is positioned between the top surface of the glass substrate and the bottom surface of the glass substrate and crosses the glass substrate downwards from the top surface of the glass substrate to the bottom surface of the glass substrate. The through-glass interconnection structure has a flat bottom at the bottom surface of the glass substrate. The semiconductor structure further includes a redistribution layer (RDL) disposed over the top surface of the glass substrate and a semiconductor chip attached to and above the RDL.

### INCORPORATION BY REFERENCE

This present disclosure claims the benefit of Chinese Patent Application No. 202410069355.X, filed on Jan. 17, 2024, which is incorporated herein by reference in its entirety.

### TECHNICAL FIELD

The present disclosure generally relates to the field of semiconductor fabrication technology and, more particularly, relates to a semiconductor package structure and a packaging method thereof.

### BACKGROUND

In the semiconductor fabrication process, the packaging process can encapsulate a semiconductor component, such as one or more chip(s), to form a semiconductor package structure, so as to protect the semiconductor component. Nowadays, industries make great efforts to develop the package structure with excellent characteristics. For example, in a 3D semiconductor device (such as a 3D memory device), the package structure is desired to have many advantageous characteristics, such as low cost, small size, short design time, strong protection, and/or preferable electrical property (e.g., short electrically connecting distance).

### SUMMARY

Aspects of the disclosure provide a semiconductor package structure. The semiconductor package structure includes a substrate structure that includes a glass substrate and a through-glass interconnection structure. The glass substrate has a bottom surface and a top surface opposing the bottom surface. The through-glass interconnection structure is positioned between the top surface of the glass substrate and the bottom surface of the glass substrate and crosses the glass substrate downwards from the top surface of the glass substrate to the bottom surface of the glass substrate. The through-glass interconnection structure has a flat bottom at the bottom surface of the glass substrate. The semiconductor structure further includes a redistribution layer (RDL) disposed over the top surface of the glass substrate and a semiconductor chip attached to and above the RDL.

Aspects of the disclosure provide a packaging method. The packaging method can include providing a glass substrate having a first side and a second side, preprocessing the second side of the glass substrate to form numerous indentations in a surface of the second side of the glass substrate, and encapsulating a semiconductor chip at the first side of the glass substrate. Hard particles at an interface between the surface of the second side of the glass substrate and a surface of a mold are contained in the numerous indentations in the surface of the second side of the glass substrate.

Aspects of the disclosure provide a semiconductor package system that includes the semiconductor package structure and a printed circuit board (PCB). The semiconductor package structure is attached to the PCB.

### BRIEF DESCRIPTION OF THE DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion. The following drawings are merely examples for illustrative purposes according to various disclosed embodiments and are not intended to limit the scope of the present disclosure.

FIG. 1 shows a schematic cross-sectional view of a semiconductor package structure according to an embodiment of the disclosure.

FIGS. 2A-2G show a fabrication process for making the semiconductor package structure according to embodiments of the disclosure.

FIG. 3 illustrates a flowchart of a semiconductor packaging process according to embodiments of the disclosure.

### DETAILED DESCRIPTION OF EMBODIMENTS

Reference will now be made in detail to embodiments of the invention, which are illustrated in the accompanying drawings. Wherever possible, the same reference numbers will be used throughout the drawings to refer to the same or like parts.

Although specific configurations and arrangements are discussed, it should be understood that this is done for illustrative purposes only. A person skilled in the pertinent art should recognize that other configurations and arrangements can be used without departing from the spirit and scope of the present disclosure. A person skilled in the pertinent art can recognize that the present disclosure can also be employed in a variety of other applications.

It should be noted that references in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure, or characteristic is described in connection with an embodiment, it would be within the knowledge of a person skilled in the pertinent art to effect such feature, structure, or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a”, “an”, or “the”, again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on”, “above”, and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath”, “below”, “lower”, “above”, “upper”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend laterally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

As used herein, the term “3D memory device” refers to a semiconductor device with vertically oriented strings of memory cell transistors (referred to herein as “memory strings”, such as NAND memory strings) on a laterally-oriented substrate so that the memory strings extend in the vertical direction with respect to the substrate. As used herein, the term “vertical/vertically” means nominally perpendicular to the lateral surface of a substrate.

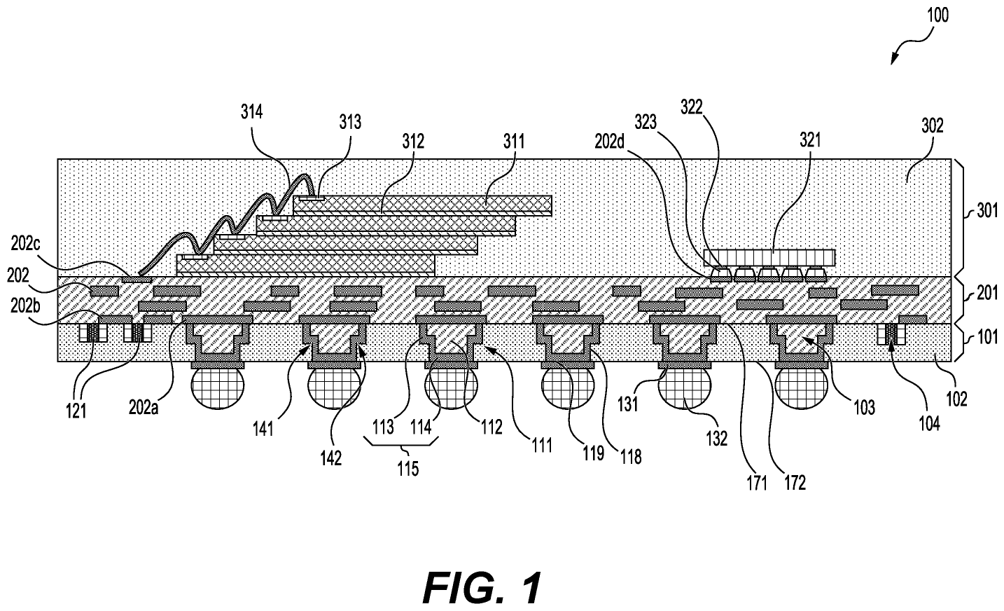

FIG. 1 shows a schematic cross-sectional view of a semiconductor package structure 100 according to an embodiment of the disclosure. The semiconductor package structure 100 includes a substrate structure 101, a redistribution layer 201, and an encapsulation layer 301.

The substrate structure 101 includes a glass substrate 102. The glass substrate 102 may include any suitable type of glass known in the art. Examples of the types of glass include photosensitive glass, borosilicate glass, soda lime glass, quartz, Pyrex, fused silica, ceramic glass, or other glass materials. In various implementations, the thickness of the glass substrate 102 can be in the range of 100 μm and 1500 μm. In some implementations, the thickness of the glass substrate 102 can be larger than 1500 μm.

The glass substrate 102 can be formed with bulk transparent glass, which is different from fiberglass typically used in reinforced epoxy cores for package substrates or printed circuit boards (PCB). In some implementations, the glass substrate 102 does not include organic material. The glass substrate 102 can include any type of bulk amorphous or polycrystalline transparent, opaque, or semi-transparent glass.

Compared with an organic package substrate or a silicon package substrate, the usage of the glass substrate 102 has many technical advantages. For example, the glass substrate 102 is more rigid than an organic substrate and thus provides better support to the semiconductor package structure 100 and reduces warpage. The glass substrate 102 allows finer line widths and line spacings in the redistribution layer 201 because of the high planarity of the glass panel of the glass substrate 102. Compared with a silicon package substrate, the glass substrate 102 has a smaller electric constant and thus can allow high-frequency signal interconnections through the glass substrate 102 or within the redistribution layer 201.

The substrate structure 101 further includes a plurality of through-glass interconnection structures 111. The glass substrate 102 can include a plurality of through-glass cavities 103. The plurality of through-glass interconnection structures 111 can be formed in the through-glass cavities 103. Each through-glass interconnection structure 111 corresponds to one respective through-glass cavity 103. The glass substrate 102 has a bottom surface 172 and a top surface 171 opposing the bottom surface 172. The through-glass interconnection structures 111 are positioned between the top surface 171 of the glass substrate 102 and the bottom surface 172 of the glass substrate 102 and cross the glass substrate 102 downwards from the top surface 171 of the glass substrate 102 to the bottom surface 172 of the glass substrate 102. The through-glass interconnection structures 111 can each have a flat bottom 119 at the bottom surface 172 of the glass substrate 102 in some implementations.

A plurality of conductive structures 132 can be disposed on the bottom surface 172 of the glass substrate 102 and below each through-glass interconnection structure 111. The conductive structures 132 are electrically coupled to the redistribution layer 201 via the through-glass interconnection structures 111.

The through-glass interconnect structure 111 can include a conductive layer 115 at sidewalls 118 and the flat bottom 119 of the through-glass interconnect structure 111. The conductive layer 115 can include two portions: a sidewall portion 113 formed on the sidewalls of the respective through-glass cavity 103, and a bottom portion 114 formed on the bottom of the respective through-glass cavity 103. The sidewall portion 113 and the bottom portion 114 of the through-glass interconnect structure 111 are connected at the bottom edge of the sidewalls of the through-glass cavity 103. The bottom portion 114 is also referred to as a conductive pad 114. In some implementations, the bottom surface of the bottom portion 114 is within the same plane as the bottom surface of the glass substrate 102.

In various implementations, the conductive layer 115 can be formed of any appropriate conductive materials, such as copper, silver, nickel, gold, aluminum, other metals, or a combination thereof, for example. In some implementations, the thickness of the conductive layer 115 can be in a range of 1 μm to 20 μm. In other implementations, the thickness of the conductive layer 115 can be thicker than 20 μm. In some implementations, the sidewall portion 113 and the bottom portion 114 can have different thicknesses.

In the FIG. 1 example, the sidewalls 118 of the through-glass interconnect structure 111 (or the sidewalls of the through-glass cavity 103) have a step shape. As shown in the cross-sectional view, the left-hand sidewall of the through-glass interconnect structure 111 has a step shape 141, and the right-hand sidewall of the through-glass interconnect structure 111 has a step shape 142. For example, the upper portion of the through-glass interconnect structure 111 has a wider lateral width than the lower portion of through-glass interconnect structure 111 in the cross-section of the through-glass interconnect structure 111. For example, the upper portion and the lower portion can have different sizes but similar shapes, such as a cylinder, a rectangular prism, a frustum, and the like. Or, the upper portion and the lower portion can have different shapes. For example, the upper portion of cavity 103 has a cylinder shape, and the lower portion of cavity 103 has the shape of a rectangular prism.

In some implementations, the sidewalls of the through-glass interconnect structure 111 may have a shape of multiple steps. In some implementations, the sidewalls of the through-glass interconnect structure 111 do not have a step shape. For example, the through-glass interconnect structure 111 as a whole has the shape of a cylinder, a prism, a frustum, and the like. In some implementations, different through-glass interconnect structures 111 may have different sizes because those different through-glass interconnect structures 111 are used for different purposes, such as signal or power transmissions. For example, some through-glass interconnect structures 111 are wider than other through-glass interconnect structures 111 in the lateral direction.

In various implementations, the conductive layer 115 is attached to the surface of each through-glass cavity 103 (including the sidewalls and the bottoms). For different possible shapes of the through-glass interconnect structures 111, the through-glass cavities 103 accordingly have different shapes consistent with the shapes of the through-glass interconnect structures 111.

According to an aspect of the disclosure, the through-glass interconnect structures 111 (or the through-glass cavities 103) are designed to have a lower aspect ratio of height over width. For example, the height of the through-glass interconnect structure 111 can be the thickness of the glass substrate 102, and the width of the through-glass interconnect structure 111 can be represented by the width of the flat bottom 119 of the through-glass interconnect structure 111. For example, the width of the bottom can be the minimum size of the flat bottom 119 of the through-glass interconnect structure 111 at the bottom surface 172 of the glass substrate 102. For example, in some implementations, the aspect ratio of the through-glass cavity 103 (height over width) can be less than 4. In various implementations, a minimum size of a flat bottom 119 of the through-glass structure 111 at the bottom surface 172 of the glass substrate 102 is larger than 100 μm.

In some examples, high aspect ratio through-glass vias (TGV) are employed for providing through-glass interconnections. For example, the aspect ratio of TGVs can be in the range of 10:1 to 50:1. Compared with the high aspect ratio TGVs, the low aspect ratio through-glass interconnect structure 111 can be formed with regular etching process and equipment and avoid expensive specific glass processing systems required for high aspect ratio TGVs. Thus, the low aspect ratio through-glass cavities 103 disclosed herein have a lower fabrication cost and can be obtained with an easier fabrication process.

In the FIG. 1 example, space 112 surrounded by the conductive layer 115 within the respective through-glass interconnection structure 111 can be filled with a dielectric material, such as a polymer dielectric material (an epoxy dielectric, for example). In other examples, space 112 can be filled with a conductive material. For example, space 112 can have the same conductive materials as the conductive layer 115.

In various implementations, the conductive structure 132 can be a solder ball, a conductive pillar, a conductive bump, and the like. The semiconductor package structure 100 can be attached to a PCB or another package substrate by employment of the conductive structure 132.

In the FIG. 1 example, the conductive structure 132 is coupled to the bottom portion 114 of the through-glass interconnection structure 111 through a conductive pad 131. The conductive pad 131 can include any suitable conductive materials, including copper, silver, nickel, gold, aluminum, other metals, or a combination thereof, for example. The conductive pad 131 is optional. In some implementations, the conductive pad 131 is not employed. In such a case, the conductive structure 132 can be in direct contact with the bottom portion 114 of the conductive layer 115.

In some implementations, the glass substrate 102 can further include a plurality of recesses 104 in the top surface of the glass substrate 102. The recesses 104 can be used to contain passive components (or referred to as passive devices) 121, and/or active components (or referred to as active devices) (not shown). Examples of passive components 121 include resistors, capacitors, inductors, diodes, transformers, or a combination thereof. Examples of active components can include circuits having transistors. The recesses 104 can have any suitable sizes or shapes for containing the respective passive or active components.

Embedding active or passive components in a package substrate, instead of positioning them above the package substrate or a redistribution layer, can save package area, thus reducing package size. Also, embedding passive or active components in the glass substrate 102 is simpler than embedding in an organic substrate in terms of the fabrication process complexity. Accordingly, fabrication costs can be lowered by employing the glass substrate 102.

The redistribution layer 201 is disposed between the substrate structure 101 and the encapsulation layer 301. The redistribution layer 201 provides wiring metal interconnects between components (such as chips or circuit components) in the encapsulation layer 302 and between the components in the encapsulation layer 302 and the through-glass interconnection structures 111. The redistribution layer 201 redistributes the input/output (I/O) access to the components in the encapsulation layer 302 to the locations of the through-glass interconnection structures 111, and further to the conductive structures 132. The through-glass interconnection structures 111 and the conductive structures 132 can be arranged to their desired locations such that the semiconductor package structure 100 can be easily connected to a PCB via the conductive structures 132. The redistribution layer 201 can be suitably designed based on the locations of the through-glass interconnection structures 111.

The redistribution layer 201 can include at least one conductive layer and at least one insulating layer. The conductive layer can include any suitable conductive materials, such as copper, silver, nickel, gold, aluminum, other metals, or a combination thereof. The insulating layer can include organic or non-organic electric materials. In the FIG. 1 example, the redistribution layer 201 includes a plurality of conductive layers 202. A top conductive layer 202 can include a plurality of top contact pads 202C and 202D that are exposed from surrounding insulating materials. A bottom conductive layer 202 can include a plurality of bottom contact pads 202A and 202B. The bottom contact pads 202A can be disposed on top of respective through-glass interconnection structures 111, being coupled to the conductive layers 115 of the respective through-glass interconnection structures 111. In various implementations, one bottom contact pad 202A can fully or partially cover the top surface of the respective through-glass interconnection structure 111. The FIG. 1 example shows a scenario where the bottom contact pads 202A fully cover the top surfaces of the respective through-glass interconnection structures 111. However, in other examples, one bottom contact pad 202A can partially cover the top surface of the respective through-glass interconnection structure 111. The bottom contact pads 202B can each be disposed to be in contact with at least one terminal of respective passive components 121 or active components.

The encapsulation layer 301 includes a plurality of semiconductor chips that are encapsulated in an encapsulation material. In the FIG. 1 example, the encapsulation layer 301 includes a group of semiconductor chips 311 and an individual semiconductor chip 321. For example, the semiconductor chips 311 can be a group of 3D memory devices. The semiconductor chip 321 can be a memory controller coupled to the 3D memory devices. The 3D memory devices and the memory controller together form a memory system, such as a solid-state drive (SSD).

The group of semiconductor chips 311 are attached to the top surface of the redistribution layer 201. Each semiconductor chip 311 is attached to the redistribution layer 201 using an adhesive layer 312. The semiconductor chips 311 are stacked vertically on top of the redistribution layer 201. Also, the semiconductor chips 311 are displaced from each other such that chip contact pads 313 disposed on the top surface of each semiconductor chip 311 can be exposed for wire bonding. Each chip contact pad 313 can be connected to a corresponding top contact pad 202C of the redistribution layer 201 using a metal wire 314 by wire boning. As shown, a chip contact pad 313 of a semiconductor chip 311 may be directly connected to a respective top contact pad 202C of the redistribution layer 201 or via a chip contact pad 313 of another semiconductor chip 311. The FIG. 1 example shows four semiconductor chips 311 stacked together, however, based on actual needs, the number of the semiconductor chips 311 may differ from four in other examples. Also, the semiconductor chips 311 may be vertically stacked on each other and/or laterally spaced apart.

The semiconductor chip 321 may have conductive structures 322 (such as conductive pillars, contact pads, or the like) that are each electrically coupled to a respective top contact pad 202D of the redistribution layer 201 via a conductive structure 323, such as a solder ball, a conductive bump, or the like.

The encapsulation layer 302 can include an epoxy molding compound (EMC) to seal the semiconductor chips 311 and 321. The encapsulation layer 302 not only provides mechanical protection for the semiconductor package structure 100 but also prevents external moisture and dust from accessing the semiconductor chips 311 and 321, the metal wires 314, the interconnect structures 322 and 323, and the top contact pads 202C and 202D.

In various implementations, the plurality of chips encapsulated in the encapsulation layer 302 can be any type or number of semiconductor chips and arranged in any suitable way. Examples of such semiconductor chips can include, but not limited to, system-on-a-chip (SoC) die, processing chip (digital signal processor (DSP), application-specific integrated circuit (ASIC), central processing unit (CPU), graphics processing unit (GPU)), memory chip (volatile memory (e.g., dynamic random-access memory (DRAM)), nonvolatile memory (e.g., read-only memory (ROM)), flash memory, solid state memory), and the like.

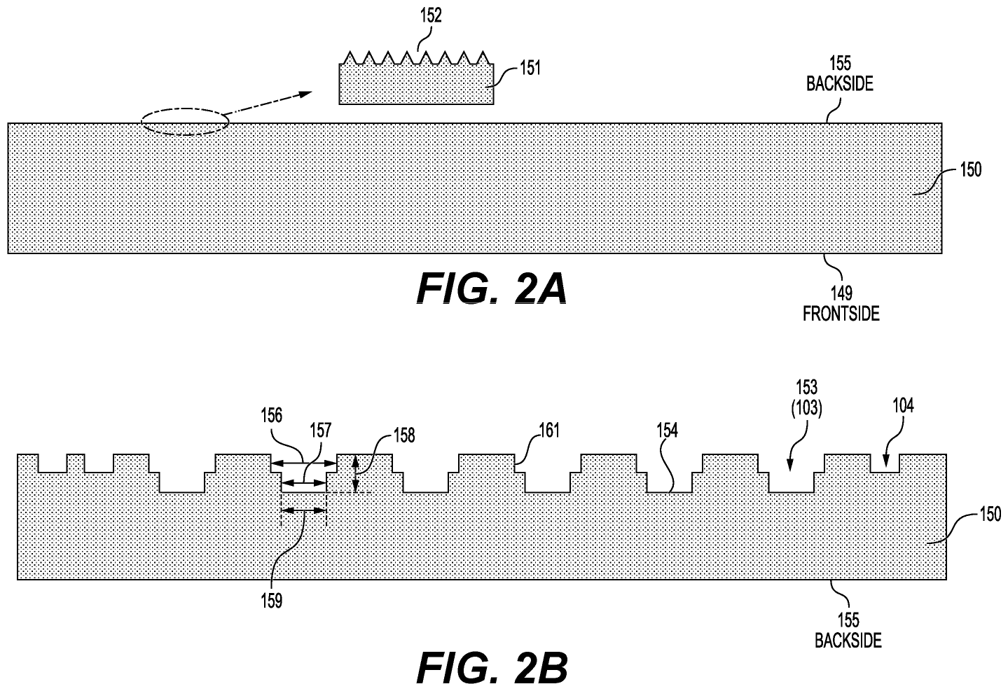

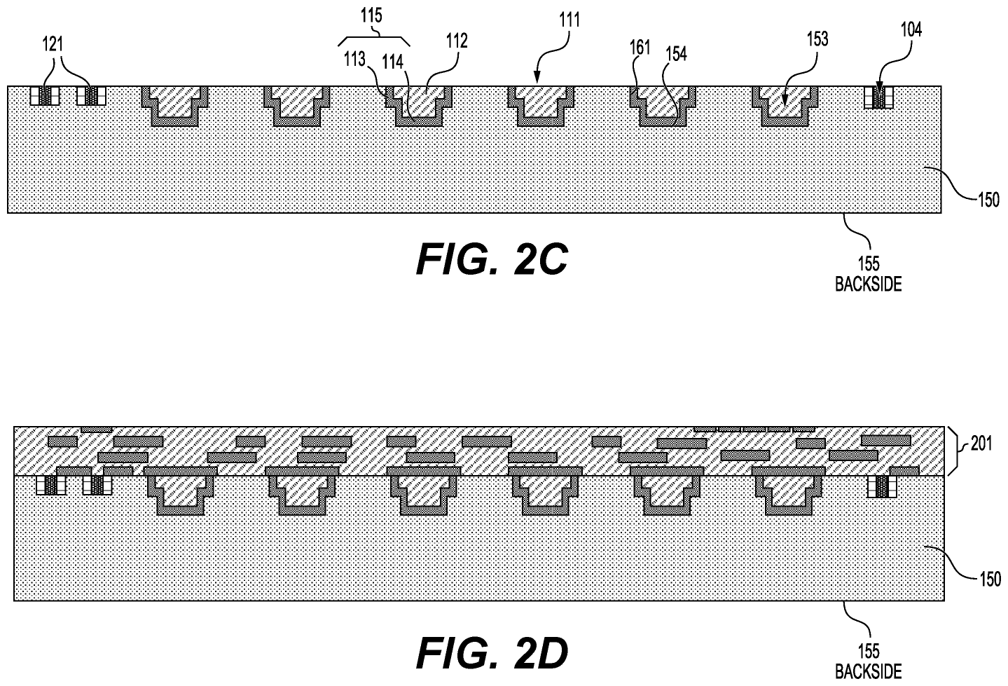

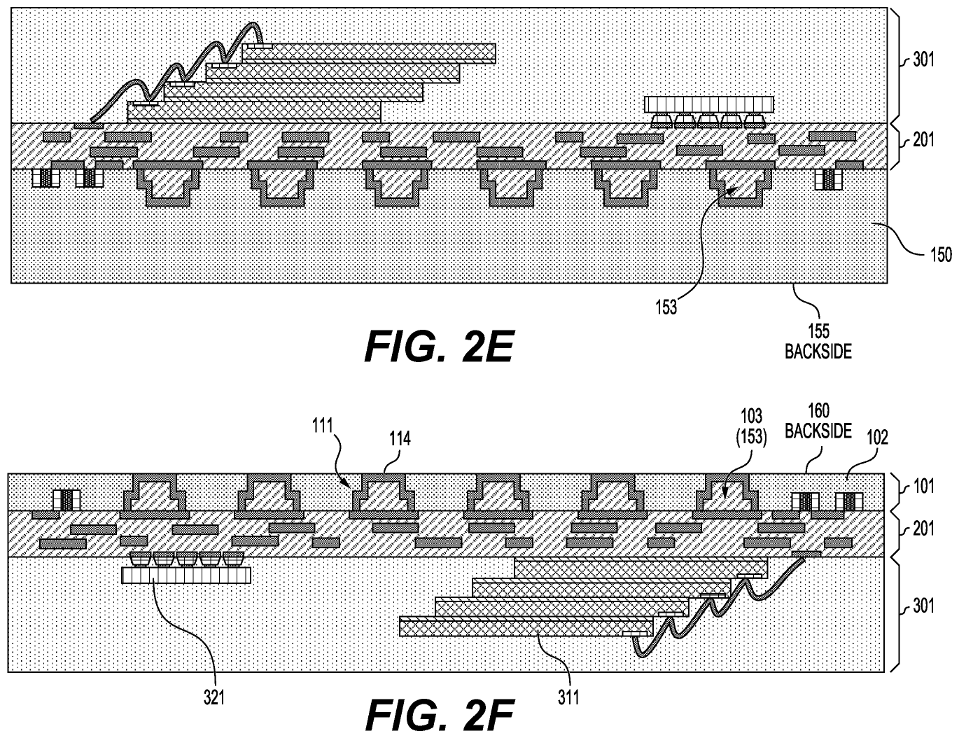

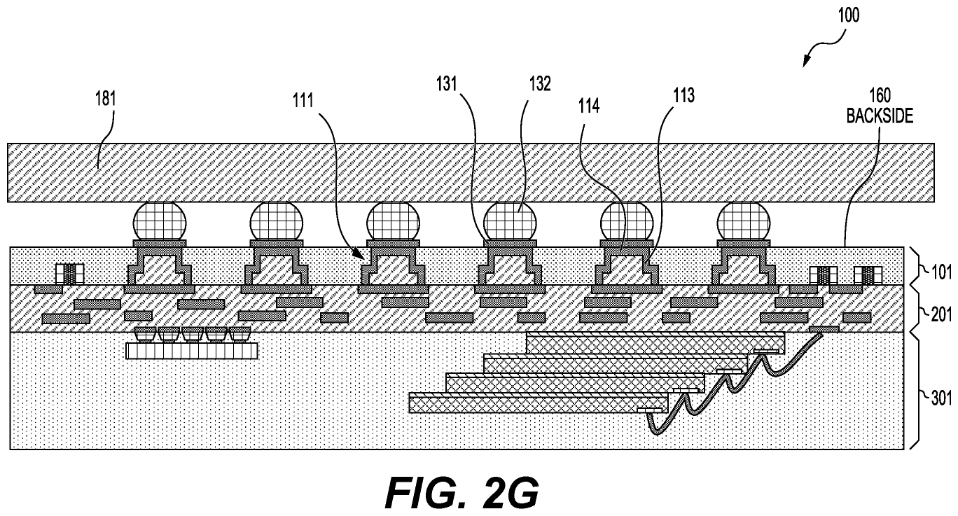

FIGS. 2A-2G show a fabrication process for making the semiconductor package structure 100 according to embodiments of the disclosure. Schematic cross-sectional views of a sequence of semiconductor structures are illustrated. Each semiconductor structure in the sequence corresponds to a stage of the fabrication process. Several technical advantages associated with the fabrication process are explained.

In FIG. 2A, a glass substrate 150 is provided. The glass substrate 150 may include any suitable type of glass known in the art, including but not limited to photosensitive glass, borosilicate glass, soda lime glass, quartz, or other glass materials. The glass substrate has a frontside (first side) 149 and a backside (second side) 155. A preprocessing is performed at the backside 155 of the glass substrate 150 to form numerous indentations 152. A zoomed-in view of a portion 151 of the backside surface of the glass substrate 150 is illustrated to show the indentations 152.

According to an aspect of the disclosure, the indentations 152 can be employed to prevent the glass substrate 150 from being damaged or reduce such damage during the later-performed molding process. For example, during the molding process, the glass substrate 150 with semiconductor chips attached thereon is disposed in a mold cavity between a top mold and a bottom mold. EMC is injected into the mold cavity. The backside surface of the glass substrate 150 is pressed against the top surface of the bottom mold with high pressure. Hard particles existing on the interface between the backside surface of the glass substrate 150 and the top surface of the bottom mold can potentially damage the glass substrate 150. For example, microcracks and mechanical stress may be induced within the glass substrate 150, negatively affecting the yield rate. Measures may be adopted to clean the mold or the glass substrate 150, but it is difficult to remove the hard particles thoroughly. By preprocessing the backside 155 of the glass substrate 150, the resulting indentations can contain the hard particles, eliminating or reducing the pressure against the glass substrate 150 caused by the hard particles during the molding process. Accordingly, the yield rate can be improved.

In various implementations, the indentations 152 can have various shapes (or profiles) and sizes in a cross-section. In some examples, the width and depths of the indentations 152 can be in a range of 5 μm to 15 μm. In some examples, the width and depths of the indentations 152 can be in a range of 2 μm to 25 μm. In some examples, the width and depths of the indentations 152 can be in a range different than the above ranges. The indentations 152 can have the shape of a hemisphere, cone, truncated cone, cylinder, tetrahedron, pyramid, conical frustum, octagonal prism, truncated pyramid, cuboid, hexagonal prism, and the like. The indentations 152 may have an irregular shape. The indentations 152 can be a pit, a recess, a cavity, and the like. The indentations 152 may have an elongated shape. For example, the indentations 152 can be slots, trenches, and the like.

The indentations 152 may be formed using any suitable glass-processing process, such as crack-free laser drilling, a laser ablation process, a mediablasting or sandblasting process, an ultrasonic drilling process, or an etching process (such as a chemical wet etching process or a dry reactive ion etching process), or a combination of these processes. In some embodiments, the indentations 152 may be formed by exposing a photoimageable glass to ultraviolet (UV) light. For example, a mask material may be used to define the area of the photoimageable glass that is exposed to ultraviolet light. The masked photoimageable glass may be exposed to ultraviolet light and heated to an elevated temperature causing a change of the structural and/or chemical properties of the area exposed to ultraviolet light, such that the exposed area may have a higher etch rate than the unexposed area of the photoimageable glass. The indentations 152 may be etched in the exposed area of the photoimageable glass using an acid, such as hydrofluoric acid (HF), ethylenediamine pyrocatechol, potassium hydroxide/isopropyl alcohol, tetramethylammonium hydroxide, and the like.

In FIG. 2B, a plurality of blind cavities 153 and a plurality of recesses 104 are formed in the frontside surface of the glass substrate 150. The blind cavities 153 are later transformed into through-glass cavities 103 shown in FIG. 1. The blind cavities each have a flat bottom 154. The blind cavities 153 and the recesses 104 can be arranged at desired locations. Any suitable glass-processing processes, as described with reference to FIG. 2A, can be used to form the blind cavities 153 and the recesses 104. The glass substrate 150 in FIG. 2B is flipped over compared with FIG. 2A, and the backside 155 of the glass substrate 150 is now facing downwards.

The shapes and sizes of the recesses 104 can be controlled suitably for embedding passive or active components. Because glass substrate 150 is adopted for the semiconductor package structure 100, the complexity of the fabrication process for forming the recesses 104 is reduced compared with using organic substrate.

The shapes and sizes of the blind cavities 153 can vary in different implementations. In some implementations, sidewalls 161 of the cross-section of the blind cavities 153 have a step shape. For example, to form a blind cavity 153 with step-shaped sidewalls 161, a first shallow cavity with a larger width 156 can first be formed in the frontside surface of the glass substrate 150, and subsequently, a second shallow cavity with a smaller width 157 can be formed at the bottom of the first cavity. Forming the blind cavities 153 in such a manner (stacking multiple shallow cavities) simplifies the fabrication process and lowers the requirement for expensive glass-handling equipment, resulting in a lower fabrication cost.

Also, the aspect ratio of the blind cavity 153 (height 158 over bottom width 159) is relatively high compared with a through-glass hole or blind hole structure employed in the art. The high aspect ratio lowers the fabrication cost.

In FIG. 2C, the plurality of through-glass interconnection structures 111 are formed in the plurality of blind cavities 153. Each through-glass interconnection structure 111 includes a conductive layer 115 (a sidewall portion 113 and a bottom portion 114) attached on the sidewalls 161 and the plat bottom 154 of the respective blind cavity 153. The space 112 surrounded by the conductive layer 115 is filled with a polymer dielectric material, for example. Also, the plurality of passive components 121 or active components are embedded in the plurality of recesses 104.

In an example fabrication process, passive components 121 or active components can be embedded in the recesses 104. For example, the passive components 121 or active components can be previously made and ready to be dropped into the recesses 104. Adhesive material(s) may be used to affix the passive components 121 or active components to the recesses 104. Subsequently, to form the through-glass interconnection structures 111, a seed layer can first be formed on the frontside of the glass substrate 150 to cover the internal surfaces of the blind cavities 153 as well as the frontside surface of the glass substrate 150. In an example, the sputtered Ti—Cu is deposited as the seed layer (also functions as a barrier layer).

A mask layer can then be formed over the seed layer to expose the blind cavities 153 but cover other areas on the frontside surface of the glass substrate 150. Copper metallization can be performed, for example, by electroplating or any other suitable method to cover the sidewalls and bottoms of the blind cavities 153 with a conductive layer 115. A polymer dielectric material can be filled into the spaces 112 in the blind cavities 153. A chemical mechanical polishing (CMP) process can be performed to remove the excessive polymer dielectric material, the deposited copper layer, and the mask above the front surface of the glass substrate 150. An etching process can be performed to remove the seed layer on the front surface of the glass substrate 150. Top surfaces of the passive components 121 or active components are also exposed.

In FIG. 2D, the redistribution layer 201 is formed on top of the glass substrate 150. Any suitable fabrication methods known in the art can be employed for forming the redistribution layer 201.

In FIG. 2E, the encapsulation layer 301 is formed on top of the redistribution layer 201. Any suitable fabrication methods known in the art can be employed for forming the encapsulation layer 301. For example, the semiconductor chips can first be attached to the top surface of the redistribution layer 301, followed by a molding process to encapsulate the semiconductor chips with EMC.

In FIG. 2F, the glass substrate 150 is thinned to expose the bottom portion 114 of the conductive layer 115 of each through-glass interconnection structure 111. The glass substrate 150 is transformed into the glass substrate 102. The backside 155 of the glass substrate 150 becomes the backside 160 of the glass substrate 102. The blind cavities 153 are transformed into the through-glass cavities 103. The substrate structure 101 results from the operations of thinning the glass substrate 150. The semiconductor structure in FIG. 2E is flipped over in FIG. 2F. The backside 160 of the glass substrate 102 is now facing upwards.

In some implementations, a grinding and/or polishing process, such as a CMP process, can be performed to remove the layer of glass above the current backside surface of the glass substrate 102 to expose the bottom portion 114 of the conductive layer 115. Other thinning methods may be used in some implementations, such as wet or dry etching or glass-processing processes as described with reference to FIG. 2A.

In the fabrication process disclosed herein, the thick glass substrate 150 is used originally until the semiconductor chips 311 and 321 are encapsulated during an EMC molding process, and the thick glass substrate 150 is then transformed into the thin glass substrate 102 by removing a glass layer. The removed glass layer can serve as a protection layer preventing the substrate structure 101 from being damaged. For example, due to the additional thickness of the removed glass layer, the glass substrate 150 can have a higher mechanical strength and better withstand external pressure and impact, reducing the risk of breakage during the fabrication process (including EMC molding). Also, the removed glass layer prevents the backside 160 from being dented, resulting in a smooth backside surface of the semiconductor package structure 100. Thus, the fabrication process disclosed herein helps to improve the yield rate.

In FIG. 2G, the plurality of conductive structures 132, such as solder balls, are implanted at the backside 160 of the glass substrate 102. The conductive structures 132 are electrically coupled to the conductive pads 114 of respective through-glass interconnection structures 111. In some implementations, the plurality of conductive pads 131 are formed between the conductive pads 114 and the conductive structures 132. In case a grinding and/or polishing process performed in the previous step to expose the conductive pads 114 has fully or partially eliminated the conductive pads 114, the additional conductive pads 131 can serve as an intermediate interconnect structure to connect the conductive structure 132 to the sidewall portion 113 of the respective through-glass interconnect structure 111. Such conductive pads 131 can relax the requirements of the grinding and/or polishing process. Also, such conductive pad 131 can improve the reliability of the interconnection structures. In some implementations, the conductive pads are not employed. At the current stage, the semiconductor package structure 100 is formed.

In FIG. 2G, an additional fabrication step is shown to form a semiconductor package system. Specifically, the semiconductor package structure 100 is attached to a PCB 181. The resulting semiconductor package system includes the semiconductor package structure 100 and the PCB 181. Various types of PCBs may be employed in various implementations to provide the PCB 181. Depending on the conductive structure 132, various methods can be employed to bond the semiconductor package structure 100 with the PCB 181.

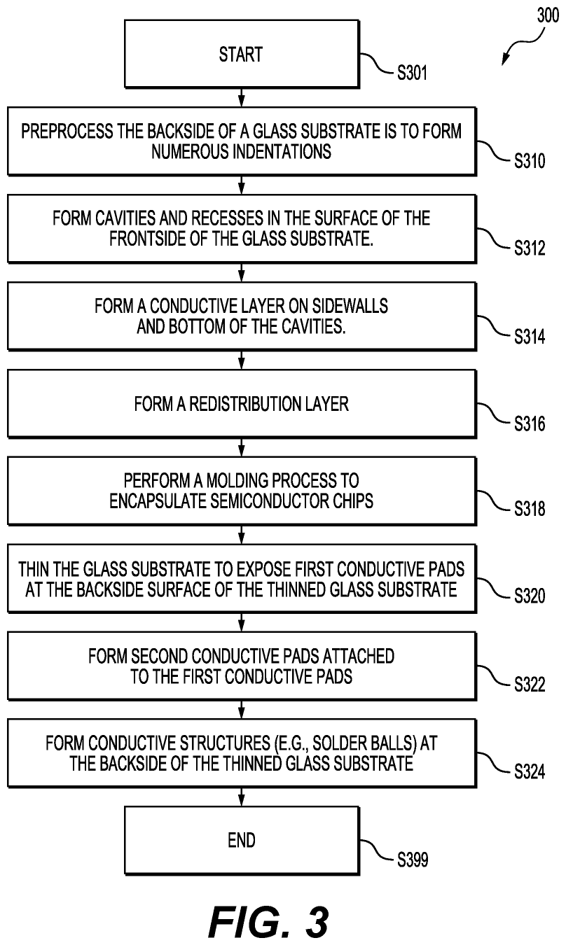

FIG. 3 illustrates a flowchart of a semiconductor package structure fabrication process 300 (or a semiconductor packaging process 300) according to embodiments of the disclosure. The process 300 can be performed to fabricate the semiconductor package structure 100. The steps in the process 300 can be performed in a different order or in parallel in some examples. Not all steps are performed in some examples. The process 300 can start from S301 and proceed to S310.

At S310, a glass substrate having a frontside (first side) and a backside (second side) can be provided. The backside of the glass substrate is preprocessed to form numerous indentations in the backside surface of the glass substrate.

At S312, a plurality of cavities can be formed in the surface of the frontside of the glass substrate. The cavity can be blind cavities and have a flat bottom. Also, a plurality of recesses can be formed in the surface of the frontside of the glass substrate.

At S314, a conductive layer can be formed on sidewalls and the flat bottom of each cavity. A portion of the conductive layer on the flat bottom of the respective cavity functions as a first conductive pad for planting, for example, a solder ball thereon. Also, a plurality of passive or active devices (components) can be embedded into the plurality of recesses, respectively. The space within the conductive layer can be filled with a dielectric material(s) in an example. The conductive layer and the dielectric material(s) form a through-glass interconnection structure in each blind cavity.

At S316, a redistribution layer can be formed over the glass substrate at the frontside of the glass substrate.

At S318, a plurality of semiconductor chips can be mounted over the redistribution layer. A molding process can be performed at the frontside of the glass substrate to encapsulate the semiconductor chips.

At S320, the glass substrate is thinned from the backside of the glass substrate to expose the first conductive pads at the backside surface of the thinned glass substrate.

At S322, a plurality of second conductive pads are formed and attached to the first conductive pads, respectively.

At S324, a plurality of conductive structures can be formed at the backside of the thinned glass substrate. Each conductive structure is coupled to the respective first conductive pad through the respective second conductive pad. Examples of the conductive structures include a solder ball, a conductive pillar, a conductive bump, and the like. The process 300 can proceed to S399 and terminate at S399.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A semiconductor package structure, comprising:
a substrate structure including a glass substrate and a through-glass interconnection structure, the glass substrate having a bottom surface and a top surface opposing the bottom surface, the through-glass interconnection structure being positioned between the top surface of the glass substrate and the bottom surface of the glass substrate and crossing the glass substrate downwards from the top surface of the glass substrate to the bottom surface of the glass substrate, the through-glass interconnection structure having a flat bottom at the bottom surface of the glass substrate;
a redistribution layer (RDL) disposed over the top surface of the glass substrate; and
a semiconductor chip attached to and above the RDL.

2. The semiconductor package structure of claim 1, wherein a minimum size of the flat bottom of the through-glass interconnection structure at the bottom surface of the glass substrate is larger than 100 μm.

3. The semiconductor package structure of claim 1, wherein a ratio of a minimum size of the flat bottom of the through-glass interconnection substructure at the bottom surface of the glass substrate to a thickness of the glass substrate is larger than ¼.

4. The semiconductor package structure of claim 1, wherein the through-glass interconnection structure includes a conductive layer covering an outer surface of a sidewall and the flat bottom of the through-glass interconnection structure.

5. The semiconductor package structure of claim 1, wherein the through-glass interconnection structure has a step shape in a vertical cross-section of the through-glass interconnection structure at each of a first side and second side of the through-glass interconnection structure, the first side opposing the second side.

6. The semiconductor package structure of claim 1, wherein the through-glass interconnection structure has a lower portion and an upper portion stacked on top of the lower portion, and the upper portion is wider than the lower portion in a vertical cross-section of the through-glass interconnection structure.

7. The semiconductor package structure of claim 1, further comprising:
a conductive pad that is attached to the flat bottom of the through-glass interconnection structure; and
a conductive structure attached to the conductive pad.

8. The semiconductor package structure of claim 1, further comprising:
a conductive structure attached to the flat bottom of the through-glass interconnection structure, the conductive structure including one of a solder ball, a conductive pillar, and a conductive bump.

9. The semiconductor package structure of claim 1, further comprising:
a passive device embedded in the top surface of the glass substrate.

10. A packaging method, comprising:
providing a glass substrate having a first side and a second side;
preprocessing the second side of the glass substrate to form numerous indentations in a surface of the second side of the glass substrate; and
encapsulating a semiconductor chip at the first side of the glass substrate.

11. The packaging method of claim 10, wherein hard particles at an interface between the surface of the second side of the glass substrate and a surface of a mold are contained in the numerous indentations in the surface of the second side of the glass substrate.

12. The packaging method of claim 10, further comprising:
forming a cavity in a surface of the first side of the glass substrate, the cavity having a flat bottom;
forming a through-glass interconnection structure in the cavity, the through-glass interconnection structure including a conductive layer formed on an outer surface of a sidewall and the flat bottom of the cavity, the through-glass interconnection structure having a flat bottom at the flat bottom of the cavity; and
after the encapsulating the semiconductor chip at the first side of the glass substrate, thinning the glass substrate from the second side of the glass substrate to expose the flat bottom of the through-glass interconnection structure.

13. The packaging method of claim 12, further comprising:
After the thinning the glass substrate from the second side of the glass substrate, forming a conductive structure at the second side of the glass substrate, the conductive structure being coupled to the conductive layer of the through-glass interconnection structure at the flat bottom of the cavity, and the conductive structure including one of a solder ball, a conductive pillar, and a conductive bump.

14. The packaging method of claim 13, further comprising:
forming a conductive pad attached to the flat bottom of the through-glass interconnection structure, the conductive structure being attached to the conductive pad.

15. The packaging method of claim 12, wherein a minimum size of the flat bottom of the through-glass interconnection structure at the bottom surface of the glass substrate is larger than 100 μm.

16. The packaging method of claim 12, wherein a ratio of a minimum size of the flat bottom of the through-glass interconnection structure at the bottom surface of the glass substrate to a thickness of the glass substrate after the thinning is larger than ¼.

17. The packaging method of claim 12, wherein the through-glass interconnection structure has a step shape in a cross-section of the through-glass interconnection structure at opposite sides of the through-glass interconnection structure.

18. The packaging method of claim 12, further comprising:
forming a recess in the surface of the first side of the glass substrate; and
disposing a passive device into the recess.

19. The packaging method of claim 10, wherein a width or a depth of the numerous indentations is in a range of 5 μm to 15 μm.

20. A semiconductor package system, comprising:
a semiconductor package structure including:
a substrate structure including a glass substrate and a through-glass interconnection structure, the glass substrate having a bottom surface and a top surface opposing the bottom surface, the through-glass interconnection structure being positioned between the top surface of the glass substrate and the bottom surface of the glass substrate and crossing the glass substrate downwards from the top surface of the glass substrate to the bottom surface of the glass substrate, the through-glass interconnection structure having a flat bottom at the bottom surface of the glass substrate,
a redistribution layer (RDL) disposed over the top surface of the glass substrate, and
a semiconductor chip attached to and above the RDL; and
a printed circuit board (PCB), the semiconductor package structure being attached to the PCB.
